(19) United States
(12) Patent Application Publication
(10) Pub. No.: US 2009/0267897 A1
(43) Pub. Date: Oct. 29, 2009

(54) REMOTE CONTROL TRANSMITTER

(75) Inventor: Kenji Ootsuka, Tokyo (JP)

Correspondence Address: DARBY & DARBY P.C., P.O. BOX 770, Church Street Station, New York, NY, 10008-0770, US

(73) Assignee: SMK Corporation, Tokyo (JP)

(21) Appl. No.: 12/362,083

(22) Filed: Jan. 29, 2009

(30) Foreign Application Priority Data
Apr. 23, 2008 (JP) 2008-113070

(51) Int. Cl. G06F 3/033; H03K 17/94; G08B 21/00

(52) U.S. Cl. 345/158; 341/20; 340/686.1

(57) ABSTRACT

A remote control transmitter detects motion in a specific direction or in a rotational direction around a specific axis: The transmitter includes a battery placed on a bottom surface side within a case containing circuitry of the transmitter. The bottom surface side has a convex surface, with a center of curvature C coincident in the upward direction of the force of gravity above a center of gravity G of the transmitter. When placed on a flat surface, the transmitter assumes a stable orientation such that when the transmitter is grasped in order to perform a motion-based operation, it can be can be assumed that the vertical direction is the direction of the line joining the center of curvature C of the stable portion to the center of mass G, as an absolute direction for reference in detecting the motion operation.

### CROSS REFERENCE TO RELATED APPLICATION

This application claims the benefit under 35 U.S.C. §119 of Japanese Patent Application No. 2008-113070, filed on Apr. 23, 2008, which is hereby incorporated by reference herein in its entirety.

### FIELD OF INVENTION

The present invention relates to a remote control transmitter for controlling remotely a device to be controlled, such as a household electronic device, and more specifically, to a remote control transmitter performing a specific action on the device to be controlled via a shaking or rotating operation performed on the remote control transmitter.

### BACKGROUND OF THE INVENTION

Conventionally, remote control transmitters have been provided with a plurality of operating switches corresponding to individual control data for controlling remotely devices to be controlled. In addition, remote control transmitters have been provided for controlling remotely a device in accordance with a shaking or rotating motion operation on the remote control transmitter itself, in order to eliminate some or all of the operating switches that are attached to the case, and in order to enable more simple input operations.

A remote control transmitter of this latter type that recognizes a motion operation on the transmitter may have an acceleration sensor for detecting acceleration in two axial directions or three axial directions, or a gyroscope for detecting angular velocity around an axis attached within the case, to detect from the acceleration of the case itself in an axial direction, or from the angular velocity of the case itself around an axis, the relative direction of motion or the direction of rotation of the case, and then to send to the device to be controlled control data in accordance with the input operation of the direction of motion or the direction of rotation.

However, these motion sensors, such as acceleration sensors and gyroscopes, detect only the direction of relative motion of the case or the direction of rotation of the case, and do not detect the absolute direction of motion in the vertical direction or horizontal direction. Thus, there is a problem in that different control data could be outputted with the same motion operation by the user depending on the orientation of the case or the direction in which the user grasps the case.

Given this problem, a remote control transmitter has been proposed wherein an absolute direction is obtained in the horizontal direction and the orientation of the case relative to the geomagnetic field is obtained through the joint use of a magnetic sensor, and the vertical direction is obtained as an absolute direction by calculating the direction of gravity through a combination of acceleration detected in three axial directions by an acceleration sensor that detects the acceleration in three mutually orthogonal axial directions, and for detecting the direction of motion of the case and direction of rotation around an axis using these absolute directions as references (see, e.g., Japanese Unexamined Patent Application Publication 2007-241655, hereinafter “Patent Reference 1,” which is incorporated by reference in its entirety herein).

In the remote control transmitter set forth in Patent Reference 1, a gravity vector is calculated from the acceleration that is detected by the acceleration sensor, in a state wherein the remote control transmitter is still, and when a motion operation of the remote control transmitter itself is detected, the gravity vector portion is subtracted from the detection value of the acceleration sensor detect the absolute direction of motion and direction of rotation of the motion operation.

There is also a known remote control transmitter wherein a motion sensor is supported floating within the case of the remote control transmitter, so that the motion sensor is always in a uniform position relative to the direction of gravity. (see, e.g., Japanese Unexamined Patent Application Publication H6-50758, hereinafter “Patent Reference 2,” which is incorporated by reference in its entirety herein).

However, in this conventional remote control transmitter wherein the calculation is performed by subtracting the gravity vector component from the detected value by the acceleration sensor, it is necessary to perform complicated calculations to correct the gravity vector component each time a motion operation is detected. Because of this, the detection of a motion operation for an absolute direction or a rotation around an absolute direction is slow, requiring the use of a microprocessor with sophisticated processing capabilities for the calculation.

Notably, even when an absolute direction is obtained for the horizontal direction using a magnetic sensor, the geomagnetic field sensor is not attached in the case so as to always detect the geomagnetic field vector in the horizontal direction, so it is not possible to detect the difference between a detection angle between a geomagnetic field vector in the horizontal plane and the measurement direction versus a magnetic inclination between the horizontal plane and the geomagnetic field vector, and so in so far as the vertical direction or a horizontal direction that is orthogonal to the vertical direction is not specified, the absolute direction and the angle of rotation around an axis in an absolute direction cannot be detected accurately using the geomagnetic field sensor.

Furthermore, in a remote control transmitter wherein the motion sensor is suspended through floating, a mechanism to suspend the motion sensor through floating must be provided within a case of a limited size, where this mechanism is not only complex, but requires extra components, leading to high costs, and is not suitable for practical use.

Additionally, because in remote control transmitters for remotely controlling home electronic devices, the control is through control signals of different formats for each device, multiple remote control transmitters for controlling respective devices end up being placed on a table, which becomes disorderly and unsightly.

### SUMMARY OF THE INVENTION

The present invention is the result of contemplation on these conventional problem areas, and the object thereof is to provide a remote control transmitter able to detect a motion operation in a specific axial direction or in a direction of rotation around a specific axis with the vertical direction as a reference, using a simple structure.

Furthermore, an object of the present invention is to provide a remote control transmitter that is not unsightly when placed on a table, having the visual appearance of a figurine that performs a wobbling motion.

In addition, an object of the present invention is to provide a remote control transmitter which does not fall over and fall down from its location of placement, and which does not move from its location of placement, despite being a figurine wherein the case is an egg shape.

In order to achieve the object set forth above, the remote control transmitter according to the present invention includes a motion sensor for detecting acceleration along a predetermined axis or the angular velocity around a predetermined axis and for outputting a detection signal; a control circuit element for detecting, from the detection signal that is outputted from the motion sensor, a motion operation on a case thereof, and for generating a specific control data in accordance with a detected motion operation. An RF module is provided for transmitting the control data to the device to be controlled using a radio signal; and a battery is provided for supplying the driving power supply to the motion sensor, the control circuit element, and the RF module. Each of these components is contained in a case, and an associated device to be remotely controlled is controlled remotely through control data generated through a motion operation on the case.

At least an outer peripheral surface of the bottom surface side of the case is a convex surface, and a battery is disposed on the bottom surface side within the case, to produce a center of gravity G of the remote control transmitter device as a whole that lies below the center of curvature of the convex surface. A stable portion for causing the case to be oriented stably is formed on the outer peripheral surface of the bottom surface side so that the center of curvature C of the outer peripheral surface will be coincident in the upward direction of gravity from the center of gravity G; defining the direction of the axial line connecting the center of curvature C of the stable portion to the center of gravity G as the vertical direction. The motion sensor is positioned in the case so as to detect an acceleration in a predetermined axial direction or an angular velocity around a predetermined axis of rotation, using the vertical direction as a reference; and the control circuit element detects the motion operation of the case itself from the detection signal that is outputted from the motion sensor.

In the state wherein the remote control transmitter is placed on the outer peripheral surface around the stable portion, the overall gravitational force on the case that includes the various components that act on the center of gravity G act so as to rotate the convex surface in the direction of the stable portion. While the case wobbles centered on the stable portion, the case assumes a stable orientation in the stable portion wherein the axial line connecting the center of curvature C and the center of gravity G is coincident with the vertical direction. Even when this case, in its stable orientation, is grasped and a motion operation is performed, the vertical direction of the case is generally unchanged, and with the direction of the axial line that connects the center of curvature C of the stable portion to the center of gravity G being the vertical direction, when the motion sensor is positioned in the case so as to detect acceleration in a predetermined axial direction or detect an angular velocity around a predetermined axis, using the vertical direction as a reference, then it is possible for the control circuit element to detect the motion operation of the case itself from the motion sensor detection signal, with the vertical direction, being an absolute direction, as the reference.

In accordance with an embodiment of the present invention, the motion sensor comprises a Z acceleration sensor positioned in the case so as to detect an acceleration in the vertical axial direction, with the vertical axial direction as a reference, or a gyroscope positioned in the case so as to detect an angular velocity around the vertical axis, with the vertical axial direction as a reference.

The detection signal that is outputted from the Z acceleration sensor that is positioned in the case so as to detect the acceleration in the vertical direction, with the vertical direction as the reference, is assumed to indicate the acceleration of the case in the vertical direction, and is able to detect a motion operation of the case in the vertical direction. Furthermore, the gyroscope that is contained within the case so as to detect the angular velocity around the vertical axis, with the vertical direction as the reference, is able to detect a rotation operation around the vertical axis of the case (that is, a yaw operation) from the detected angular velocity.

In another embodiment of the present invention, a push switch having an operating button that protrudes from the outer peripheral surface of the case is also contained within the case; and the motion sensor is positioned in the case so as to detect an acceleration in a specific axial direction in the horizontal direction, or an angular velocity around a specific axis, with the vertical axial direction and the direction of the operating button around the vertical axis as references.

When the case is grasped in its stable orientation in order to perform a motion operation, and the fingers grasping the case are placed on the operating button in order to perform a pressing operation, the vertical direction of the case is generally unchanged, so the direction of the arm of the operator who is grasping the case, relative to the direction of the operating button around the vertical direction can be specified in general. Consequently, by positioning the motion sensor within the case so as to detect acceleration in a predetermined axial direction in the horizontal direction, and the angular velocity around a predetermined axis, using the vertical axial direction and the direction of the operating button around the vertical axial direction as references, it is possible for the control circuit element to detect the motion operation of the case itself for a specific direction in the horizontal direction from the detection signal of the motion sensor, with the direction of the operating button around the vertical axial direction, which is an absolute direction, as the reference.

In another embodiment of the present invention the motion sensor comprises a gyroscope for detecting an angular velocity around a specific axis in the horizontal direction.

The gyroscope detects the angular velocity around a specific axis in the horizontal direction, with the direction of the operating button around the vertical axis, which is an absolute direction, as the reference, enabling the detection of a motion operation around a specific axis. Because the direction of the arm of the operator that is grasping the case can be specified in general relative to the direction of the operating button around the vertical axis, if the direction of the arm of the operator is defined as a specific axial direction, then it is possible to detect, from the gyroscope detection signal, a rotational operation in the horizontal direction around the arm of the operator (that is, in the roll direction), or possible to detect a rotational operation in the horizontal direction that is perpendicular to the arm of the operator (that is, the pitch direction).

In another embodiment of the present invention, the motion sensor comprises a pair of X and Y acceleration sensors positioned in the case so as to detect, respectively, acceleration in the X and Y directions, which are mutually orthogonal horizontal directions, with the vertical direction as a reference.

Because even in the case of a motion operation wherein the case is grasped in the stable orientation, the vertical direction of the case does not change in general, it is possible to detect motion operations of the case in the mutually orthogonal X and Y directions in the horizontal plane from the acceleration detected by the pair of X and Y acceleration sensors that are positioned in the case so as to detect the acceleration in the mutually orthogonal X and Y directions in the horizontal plane using the vertical axial direction as a reference.

In another embodiment of the present invention, the control circuit element detects, from the detection signal that is outputted from the pair of X and Y acceleration sensors, a wobbling operation wherein the case rocks centered on the stable portion; and emitting means are provided for providing notification to the outside when two or more wobbling operations have been detected within a predetermined time period.

In the wobble operation wherein the base is caused to rock centered on the stable portion, a detection signal with a frequency of several hertz is outputted continuously over a period of several seconds from either of the pair of X and Y acceleration sensors, so the control circuit element detects the wobbling operation by assessing the motion operation of the case itself. Because the amplitude with which the case rocks due to the wobbling operation gradually attenuates, the detection value of the detection signal that is outputted from the X and Y acceleration sensors will fall below a specific threshold value, making it possible to determine the operation unit for the wobbling operation. If two or more wobbling operations are detected within a predetermined time period, then emitting means can convey to the outside to, for example, the operator this detection through, for example, the emission of light by light emitting means attached to the case of a vibration from a vibration source attached to the case, a sound outputted from a speaker, or the like.

In another embodiment of the present invention, the control circuit element detects a click operation on the case from the repetitive outputting, within a specific time period, of a detection signal with a frequency of at least 100 Hz from the motion sensor or from any of the acceleration sensors, and generates specific control data in accordance with the click operation.

With a tapping operation on a case by an operating member, such as a finger nail, a detection signal of a frequency of greater than 100 Hz is outputted from the acceleration sensor, which can be discriminated from a motion operation of the case itself or a case rocking operation, which output a detection signal with a frequency of several hertz. Consequently, when a detection signal with a frequency of greater than 100 Hz is outputted repetitively within a specific time period from the acceleration sensor, a click operation wherein the case is tapped twice in a row can be outputted, without being identified incorrectly as a different operation.

In another embodiment of the present invention, a speaker for outputting a sound in accordance with a motion operation or a click operation that is detected by the control circuit element is contained within the case.

The detail of the motion operation or click operation that is detected by the control circuit element is outputted as a sound, notifying the operator of the motion operation or click operation.

In another embodiment of the present invention, the outer peripheral surface of the case is shaped as an egg shape wherein one side in the lengthwise direction is a bottom surface side; an outer peripheral surface other than a position on either side in the lengthwise direction wherein the center of curvature of the outer peripheral surface is coincident, in the direction of the force of gravity, with the center of gravity G, is a convex surface that is on the opposite side from the stable portion, wherein the center of curvature of the outer peripheral surface is on the opposite side of the center of gravity G of the remote control transmitter as a whole; and in the stable orientation, the lengthwise direction of the egg shape is in the vertical direction.

The force of gravity of the base as a whole acting on the center of gravity G when placed on an outer peripheral surface aside from the position on either side in the lengthwise direction acts on the side of the stable portion on the location of placement on the outer peripheral surface so that the case will rotate around the stable portion to assume a stable orientation in a state wherein the placement is with the stable portion such that the lengthwise direction of the egg shape will be in the vertical direction. When the location of placement of the outer peripheral surface is on the other side of the lengthwise direction wherein the center of curvature of the outer peripheral surface and the center of gravity G are coincident with the direction of the force of gravity, the center of gravity G will be in a higher position than the center of curvature of the outer peripheral surface, and thus this orientation is unstable, and there will be a return to the stable orientation given even a slight vibration.

The present invention utilizes the fact that the weight of the battery that supplies the power to the various circuit elements within the case is heavy when compared to the other components that are contained within the case to produce easily a center of gravity G for the remote control transmitter as a whole that is below the center of curvature of the concave surface, through disposing the battery near a the bottom surface side that has an outer peripheral surface that is convex. This makes it possible to make the remote control transmitter into a figurine that performs wobbling action. Moreover, even though the outer peripheral surface of the bottom surface side is a convex surface, the position of placement does not move during wobbling, so there is no danger of rolling off of the table, or the like, and becoming broken.

Moreover, taking advantage of the fact that, in the stable orientation, the axial line connecting the center of curvature C of the stable portion with the center of gravity G is in the vertical direction, the motion sensor can be used without detecting or calculating the direction of the gravitational force vector or the geomagnetic field vector, making it possible to detect an operation in a specific axial direction, or a rotational operation around a specific axis, using the vertical axial direction, which is an absolute direction, as the reference.

Furthermore, the control data is sent to the device to be controlled using a radio signal, so no opening is provided in the case such as when sending the control data using an infrared signal, so there is no interruption of the transmission of the control data even when a case that is designed as a figurine is grasped.

In embodiments of the present invention comprising is an acceleration sensor for detecting the acceleration in a specific axial direction, or a gyroscope for detecting the angular velocity around a specific axis instead of calculating the gravitational force vector during the detection of the motion operation, a motion operation that is a motion operation in the vertical axial direction, or a rotational operation around the vertical axis (that is, a yaw operation), with the vertical axial direction being an absolute direction, can be detected.

The detection of a motion operation of the case itself for a specific direction in the horizontal direction can be obtained in embodiments of the present invention comprising a push switch, using the direction of an operating button of the push switch around the vertical axis, which is an absolute direction, as a reference, rather than detecting or calculating the direction of the gravitational force vector or the geomagnetic field vector when detecting the motion operation.

The detection of a rotational operation around an axis in a specific axial direction can be obtained, with the direction of the operating button as the reference, in embodiments of the present invention comprising a gyroscope for detecting the angular velocity around the specific axis.

The detection of a motion operation in the mutually orthogonal X and Y directions in the horizontal plane can be obtained, in embodiments of the present invention comprising a pair of X and Y acceleration sensors for detecting acceleration in the mutually orthogonal X and Y directions, rather than detecting or calculating the gravitational force vector or geomagnetic field vector when detecting the motion operation.

The transmitter may also be used as a toy that performs predetermined actions in response to the detection as responses to continuous operations, because when continuous operation of wobbling operations are detected from a detection signal outputted by the pair of X and Y acceleration sensors, the detection results are conveyed to the operator through emitting means.

Additionally, conveying to the operator details encouraging the cessation of continuous operation, as the operating results, enables a transition into a sleep mode where only the minimum required circuit elements within each circuit element are active, through stopping the wobbling action.

Remote control of the device to be controlled may be provided through specific control data generated in response to a click operation through performing a click operation wherein the case itself is tapped twice, rather than only through a motion operation on the case itself.

Embodiments of the present invention including a sound output device such as a speaker can stimulate demand for the product, as a mascot or character product, in addition to the function as a remote control transmitter, because it is possible to output a sound, or to cause the output of a verbal statement, in response to a motion operation, from the remote control transmitter that performs the wobbling action.

Furthermore, because the motion operation or click operation detected by the control circuit element can be confirmed audibly by the operator, if there is an incorrect detection or the operation is not detected, then the operator can perform the motion operation or the click operation again to send the corresponding control data reliably to be device to be controlled.

A transmitter according to the present invention may have an external shape that is an egg shape that differs widely from the visual appearance of a typical remote control transmitter, which is typically formed as a flat elongated box, enabling identification as a mascot or figurine, without a sense of confusion, even if placed on a table within the home wherein there are many other remote control transmitters.

Furthermore, because the device to be controlled can be controlled remotely by merely grasping and shaking the egg-shaped case, which is a simple shape, it is possible for even children and the elderly to enjoy performing simple inputting operations.

Furthermore, regardless of the portion of the egg-shaped case that is grasped in the hand, the control data is still transmitted as a radio signal, so there is no interruption to the transmission of the control data.

Furthermore, because a specific position is restored by the wobbling action, for example, when the transmitter is placed on a surface, there will be no breakage due to rolling off of the placement location, even though the case has the shape of an egg.

### BRIEF DESCRIPTION OF THE DRAWINGS

The invention will become more readily apparent from the Detailed Description of the Invention, which proceeds with reference to the drawings, in which:

FIG. 1 provides an oblique view of a remote control transmitter according to the present invention;

FIG. 2 provides an assembly perspective view of the remote control transmitter of FIG. 1;

FIG. 3 provides a lateral cross-sectional diagram of the remote control transmitter of FIG. 1;

FIG. 4 provides a block diagram illustrating the basic structure of the remote control transmitter of FIG. 1;

FIGS. 5(a) and 5(b) illustrate the wobbling operation of the remote control transmitter of FIG. 1, where FIG. 5(a) illustrates the remote control transmitter in the stable orientation and FIG. 5(b) illustrates the remote control transmitter during rocking motion;

FIG. 6 illustrates a use of the remote control transmitter by a user; and.

FIG. 7 illustrates another embodiment of the remote control transmitter according to the present invention.

### DETAILED DESCRIPTION OF THE INVENTION

A listing of some of the reference numerals and letters that are used in the drawings, together with descriptions of the corresponding elements, is provided below:
1, 30: Remote Control Transmitter
2: Case
5: Speaker
7: Push Switch
7a: Operating Button
8: Push Switch
8a: Operating Button
10: Three-Axis Acceleration Sensor (Motion Sensor)
10x: X Direction Sensor (X Direction Acceleration Sensor)
10y: Y Direction Sensor (Y Direction Acceleration Sensor)
10z: Z Direction Sensor (Acceleration Sensor for Detecting Acceleration in the Vertical Direction)
11: MPU (Control Circuit Element)
12: RF Communications Module
16: Battery
C: Center of Curvature
G: Remote Control Transmitter Center of Gravity
B: Stable Portion

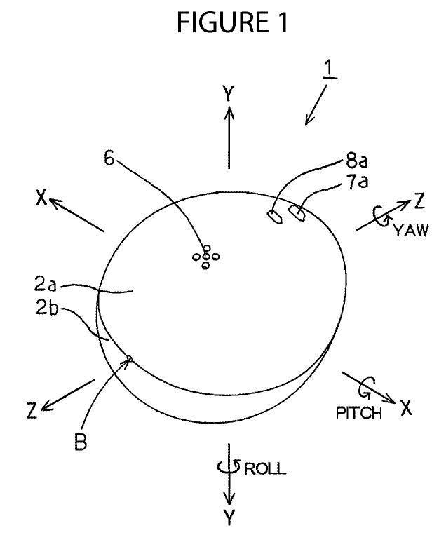

A remote control transmitter 1 as set forth in one example of an embodiment of the present invention will be explained below, with reference to FIG. 1 through FIG. 6.

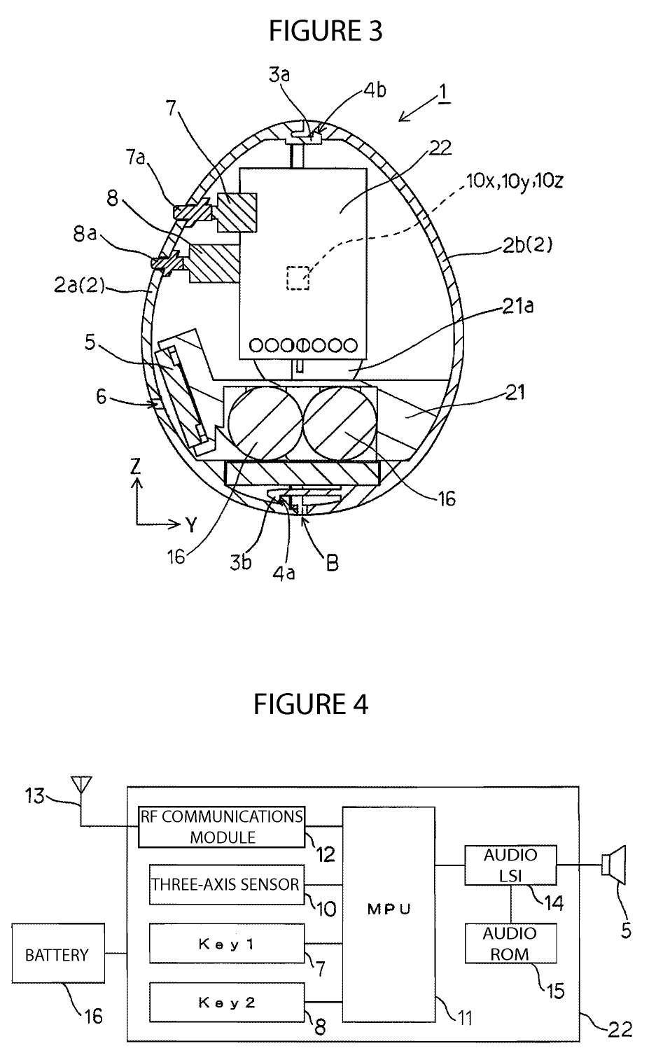

As is illustrated in these figures, in the remote control transmitter 1, the various components that are illustrated in the block diagram in FIG. 4 are contained within a case 2, which has, overall, an external peripheral surface that is an egg-shaped convex surface. In the case 2, the two ends of the egg shape in the lengthwise direction are a flat surface side (the top side in FIG. 3) and a bottom surface side (the bottom side in FIG. 3), where the curvature of the convex surface on the flat surface side has a somewhat larger curvature than that of the bottom surface side. The case 2, having this type of shape, comprises a pair of half cases 2a, and 2b, that are split in the lengthwise direction along the X-Z plane in the figure, each fabricated in a hollow cutting shape, for example, from an insulating synthetic resin.

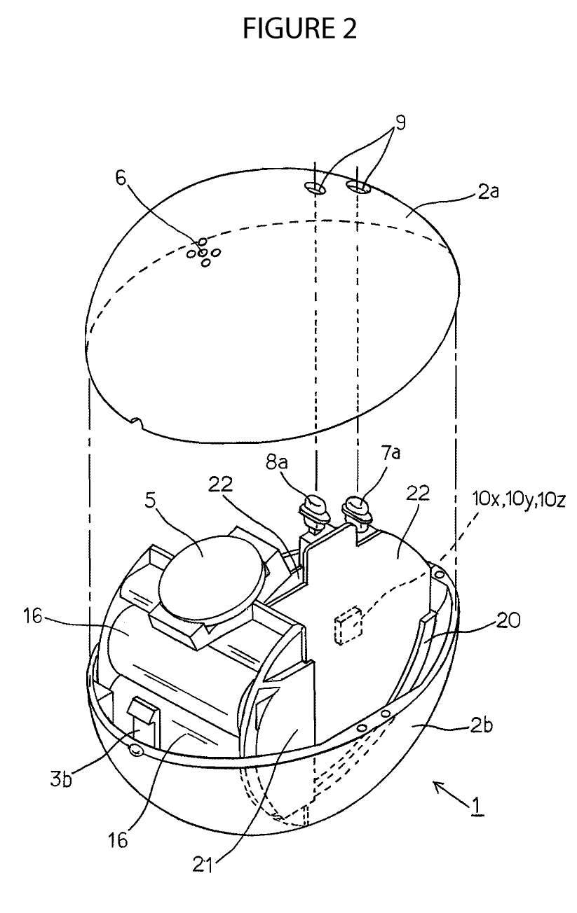

In one of the half cases 2a, a plurality of small holes 6 is provided positioned facing an attachment position of a speaker 5, described below, and through holes 9, through which the operating buttons 7a and 8a for the push switches 7 and 8 protrude are also provided. The pair of half cases 2a, and 2b may have mating protrusions 3a and 3b and mating indentations 4a and 4b, which fit together, on the back surface side and the bottom surface side of the lengthwise direction of the egg shape. As illustrated in FIG. 2, after each of the components has been placed within the half case 2b side, the mating protrusions 3a and 3b are mated with the mating indentations 4a and 4b, to assemble the two into a single unit.

Two printed circuit boards 22 are positioned and contained within the case 2 by a guide portion 21a (shown in FIG. 3) of a battery holder 21 and a positioning rib 20 that may be formed on the inside surface of one or more of the pair of half cases 2a, and 2b, where a three-axis acceleration sensor 10, a control circuit element 11, push switches 7 and 8, an RF communications module 12, a transceiver antenna 13, an audio IC 14, and an audio ROM 15, illustrated in FIG. 4, are each mounted on one of the printed circuit boards 22.

The three-axis acceleration sensor 10 comprises an X direction sensor 10x, a Y direction sensor 10y, and a Z direction sensor 10c for detecting accelerations in three mutually orthogonal acceleration directions, and is mounted in a position that is roughly in the center of the case 2 on the printed circuit board 22. The X direction sensor 10x, the Y direction sensor 10y, and the Z direction sensor 10c detect acceleration in the X direction, Y direction, and Z direction, respectively, with the vertical axial direction as the reference, with the axial line connecting the stable portion B and the center of gravity G of the remote control transmitter 1 as a whole, as will be described below, as the vertical axial line, where the specific disposition in order to detect the accelerations in the axial directions for each of these directions will be described below.

Each of the detection signals of the three-axis acceleration sensor 10, which indicate the motion operation of the remote control transmitter 1, is inputted into a microprocessor 11, which is a control circuit element, through an amplifier circuit and an A/D converter (not illustrated). The microprocessor 11 compares the detection values of the detection signals for the accelerations that are outputted from each of the sensors 10x, 10y, and 10z to respective predetermined threshold values, to produce motion operation direction data that indicates whether or not there is a motion operation in the each of the X direction, Y direction, and Z direction. The motion direction for each of the axial directions after a conversion of the polarity of the detection signal for the accelerations for each of the directions integrates the detection signal over a specific time period to obtain the speed of the motion operation, but here only the motion operation direction data, which indicates whether or not there has been a motion operation in each of the directions, will be calculated.

The remote control transmitter 1 is preferably provided with inputting means for pressing operation data, through a click operation by tapping the case 2, or through a pressing operation on the push switches 7 or 8, along with the inputting means through the motion operation of the remote control transmitter 1 (i.e., the case 2) itself.

Each of the push switches 7 and 8 are attached to one of the two printed circuit boards 22, with the respective operating buttons 7a and 8a protruding from the through holes 9 and 9 in the case 2. The position of protrusion of the operating buttons 7a and 8a are on the flat surface side in the Y direction of the half case 2a. Thus, when grasping the case 2, which is standing in the Z direction, by placing the thumb in order to operate the operating buttons 7a and 8a, the arm of the operator will extend in the X direction (se, e.g., FIG. 6).

Moreover, the microprocessor 11 monitors the frequencies of these detection signals for the acceleration that are outputted from the respective sensors 10x, 10y, and 10z, described above, to detect a click operation on the case 2 as a frequency of greater than 100 Hz, which would unlikely be produced by a motion operation of the remote control transmitter 1 itself. The frequency of the detection signal for the acceleration that is detected in a normal motion operation of the remote control transmitter 1 itself is generally on the order of several hertz. In contrast, when the outer peripheral surface of the hard case 2 is tapped by the fingertip of the operator, the frequency will be high (i.e., in excess of 100 Hz), making it possible to discriminate between the two operations based on the frequency. Here predetermined control data is generated with a click operation when the case 2 is tapped twice within 0.5 seconds. The microprocessor 11 detects the pressing operation data, indicating a click operation, when the frequency of the detection signal or the acceleration, outputted by any of the sensors 10x, 10y, and 10z is above 500 Hz twice within a 0.5 second period.

The internal ROM in the microprocessor 11 stores a table defining a relationship between the control data in the combination of the movement operation direction data and the pressing operation data that indicates either a pressing operation on the push switches 7 and 8 by pushing down the operating buttons 7a or 8a, or indicates a click operation. The microprocessor 11, when movement operation direction data and/or pressing operation data is detected, uses the table in the internal ROM to generate control data in accordance with the detected movement operation direction data and/or pressing operation data, which is then outputted to the RF communications module 12 and the audio IC 14.

For example, in one embodiment of the present invention for controlling the operation of a television receiver remotely, the microprocessor 11 generates control data as shown in Table 1 for controlling the television in accordance with the motion operation direction data and the pressing operation data.

TABLE 1

| Motion Operation | | | |
|---|---|---|---|
| Direction Data | Pressing operation Data | Control Data | Words Spoken |
| | Push switch 7 is ON | Power ON | “Okay!” |
| | | Power OFF | |
| X direction or Y direction | Push switch 8 is ON | Channel up | “Channel up” |
| X direction or Y direction | | Channel down | “Channel down” |
| Z direction | Push switch 8 is ON | Volume up | “Volume up” |
| Z direction | | Volume down | “Volume down” |
| | Push switch 8 double- | Mute | “Shhh! Be quiet!” |
| | click | | |
| | With each click operation | Analog receiver | “Analog broadcast” |
| | of the case 2 | | |
| | | Digital receiver | “Digital broadcast” |

The RF communications module 12 is provided with a radio circuit for converting into radio signals based on the Zigbee protocol (which is a short-distance radio protocol based on the IEEE 802.15.4 standard) and a signal processing circuit for executing the radio signal processes based on the Zigbee protocol. Control data that is inputted from the microprocessor 11 is sent to the device to be controlled (the television) that is paired with the remote control transmitter 1 by the Zigbee protocol from the transmitter antenna 13 as a radio signal.

The control data is sent to the device to be controlled as a video signal in the Zigbee protocol. As compared to communications using infrared signals, such as IRDA, there is no interruption in the communications signals regardless of the portion of the case 2 that is grasped when a motion operation is performed on the case 2, and it is not necessary to direct the remote control transmitter 1 in the direction of the device to be controlled, making it possible to control the device to be controlled through a motion operation, in any direction, of the remote control transmitter 1 itself. Note that the transceiver antenna 13 is attached connected to a power supply portion on a power supply pattern on the printed circuit board 22. Alternatively, an antenna pattern maybe formed from printed interconnections on the surface of the present circuit board 22.

The control data that is outputted to the RF communications module 12 is also outputted to the audio IC 14. The audio IC 14 reads out a corresponding audio signal from the audio ROM 15, and outputs that signal to the speaker 5, when there is an audio signal or spoken content stored in Table 1 in the audio ROM 15 corresponding to the inputted control data. The result is that a voice may be outputted from the speaker 5 pertaining to the control data for controlling the device to be controlled.

On the bottom surface side within the case 2, a battery holder 21 is provided for positioning and containing a battery 16, for example comprising two AA batteries, as the power supply for each of the components described above as being mounted on the printed circuit board 22. The battery holder 21 is disposed along the inner peripheral surface of the case 2, and not only positions and supports the speaker 5 in a position facing the small holes 6, but is also formed from an insulating resin of a shape that positions the two batteries 16 in the vicinity of the center of the bottom surface side of the case 2. The batteries 16, which are the heaviest compartments that structure the remote control transmitter 1, are thereby disposed at the bottom surface side of the case 2, producing a center of gravity G for the remote control transmitter 1, over all, that is lower than the center of the case 2 on the central axis (the Z axis) in the lengthwise direction (the Z direction) of the case 2.

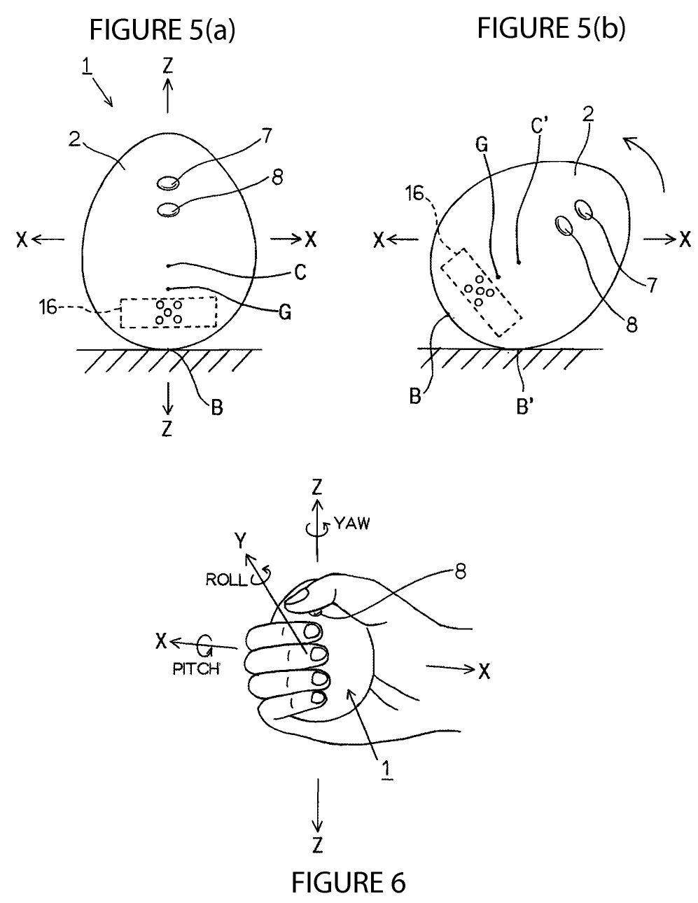

The outer peripheral surface of the case 2 is formed into an egg shape, having a contour that is round in the cross-section thereof in the horizontal direction at any position on the central axis (the Z axis) in the lengthwise direction, where the direction that is normal to the stable portion B, which intersects with the Z axis at the outer peripheral surface on the bottom surface side of the case 2 is coincident with the Z axis, so that the center curvature C of the curved surface at the stable portion B is on the Z axis. As is illustrated in FIG. 5(a), the batteries 16 are positioned so that the center of gravity G of the remote control transmitter 1 overall will be in the direction of gravitational force, or in other words, in the downwards Z direction, from the center of curvature C of the stable portion B, so that in the static state wherein no external forces are applied, the case 2 will sit on the stable portion B, and will be static in a stable orientation wherein the lengthwise direction of the egg shape will be standing in the Z direction.

On the other hand, when an external force is applied from the horizontal direction to the case 2 so as to cause a wobbling operation, the entirety of the external peripheral surface is formed as a convex curved surface, so that, as shown in FIG. 5(b), there will be a roll in the direction in which the external force is applied, and the position on which the case 2 sits will move to B′, outside of the stable portion B. Regardless of the position on the outer peripheral surface that is the sitting position B′, the center of curvature C′ of the sitting position B′ will be on the opposite side of the center of gravity G from the stable portion B, so the gravitational force of the remote control transmitter 1 acting on the center of gravity G will have the effect of causing a roll in the direction of the stable portion B, with the result that the kinetic energy will gradually dissipate during wobbling motion centered on the stable portion B, and the case 2 will come to rest in a stable orientation sitting on the stable portion B. That is, the egg-shaped remote control transmitter 1 undergoes a wobbling action, rocking back and forth centering on the stable portion B.

Note that the center of curvature of the outer peripheral surface and the center of gravity G may be coincident with the direction of gravitational force even for the external peripheral surface that intersects the Z axis on the flat surface side of the case 2; however, the curvature of the flat surface side is greater than that of the bottom surface side, and the center of gravity G will be produced at the bottom surface side, so that if the outer peripheral surface on the flat surface side is the sitting position, then the center of the curvature will be below the center of mass G in the direction of the gravitational force, which would be unstable, so the sitting position would move, either due to inertia in the rocking motion or due to a minor vibration, so that ultimately the sitting position will move to the stable orientation at the stable portion B while undergoing rocking motion.

The remote control transmitter 1, when in a stable orientation sitting on a table, or the like, when the remote control transmitter 1 is not being used, will be static in the stable orientation with the lengthwise direction of the egg shape being in the Z direction, and even when the remote control transmitter 1 is grasped in order to perform a motion operation, the Z direction will not greatly deviate from the vertical direction. Thus each of the detection directions of the three-axis acceleration sensor 10 is positioned fixedly in the case 2 so as to detect each of the directions X, Y, and Z, with the axial line joining the able portion B to the center of gravity G of the remote control transmitter 1 as a whole being the vertical axial line (the Z axis), and thus the Z direction sensor 10z for detecting the axial-direction acceleration in the Z direction is attached to the printed circuit board 22 facing, as nearly as possible, in the Z axial direction that connects the stable portion B to the center of gravity G of the remote control transmitter 1 as a whole, so as to detect the acceleration in the Z direction.

Additionally, the Y direction sensor 10y is faced so as to detect the acceleration in the Y direction towards the direction of protrusion of the operating buttons 7a and 8a around the Z axis, in the vicinity of the Z direction sensor 10z, and the X direction sensor 10x is installed facing so as to detect acceleration in the X direction that is perpendicular to the Z direction and the Y direction, in the vicinity of the Z direction sensor 10z. However, because in the present embodiment of the invention it is adequate to merely detect a motion operation in at least the horizontal direction, as shown in Table 1, it is possible to orient the X direction sensor 10x and the Y direction sensor 10y in any directions that are orthogonal to the Z direction, insofar as they can detect accelerations facing mutually orthogonal directions in the horizontal plane.

Note that in the remote control transmitter 1, the power is supplied to each circuit element from the batteries 16 rather than being received from the outside. In order to prevent the batteries 16 from wearing out, the microprocessor 11 is preferably configured to transition into a sleep mode, stopping operation of the circuit elements aside from the minimum required to detect an input operation, when no pressing operation data or motion operation direction data has been received for a predetermined period of time, such as, for example, 10 seconds.

However, when a child, or the like, repeatedly performs a wobbling operation for no other purpose than to perform the wobbling action, an input operation is detected, preventing the transition to the sleep mode, and thus there is the risk that the batteries 16 will wear out.

Given this, in the present embodiment, the wobbling operation is detected by the microprocessor 11 separately from the detection of the pressing operation data and the motion operation direction data, and if the wobbling operation continues for several times in a row, then a warning will be produced. In a wobbling operation, the detection signal or acceleration that is detected from, primarily, the X direction sensor 10x or the Y direction sensor 10y will continue with a frequency between several hertz and several dozen hertz, and when a specific amount of time (for example, about 5 seconds) elapses, the amplitude thereof will attenuate to cause the detection value of the detection signal to fall below a predetermined threshold.

Consequently, when the frequency is in the range of several hertz to several dozen hertz, and a detection signal exceeds the predetermined threshold value for more than 5 seconds, this operation is judged by the microprocessor 11 to be a wobbling operation wherein one wobbling action has been produced, and if there is another wobbling operation within 10 seconds after the detection value has fallen below the predetermined threshold value, then an audio signal corresponding to a warning is read out from the audio ROM 15 and outputted to the speaker 5. Doing so will produce a verbal warning from the speaker 5 encouraging the cessation of the wobbling operations, such as “Quit messing around—You'll wear out the batteries!” Alternatively, rather than emitting a verbal statement or an alarm sound from the speaker 5, instead a warning text, such as “DO NOT TOUCH” can be caused to appear on the outside surface of the case 2 by building in light emitting means for displaying characters inside of the case 2, which can be semi-transparent, or a vibration source can be built into the case 2, causing the case 2 to vibrate, providing a message to the operator.

Furthermore, when a series of wobbling operations is detected, the warning such as described above may, conversely, be a statement such as “I am rocking gently,” or the light emitting means may flash synchronized with the period of the rocking motion, to perform an action or make a statement in response to the wobbling operation.

The action of the remote control transmitter 1, structured in this way, will be further explained below.

The egg-shaped remote control transmitter 1, which is sitting on a table, or the like, is static in a stable orientation sitting on the stable portion B, and when an external force is applied to the remote control transmitter 1, a wobbling action is performed rocking back-and-forth centered on the stable portion B. Consequently, even though the bottom surface side of the remote control transmitter 1 is formed as a convex surface, it does not roll off the table, or otherwise fall from its placement location.

In the waiting state, wherein no external force is applied, the remote control transmitter 1 is static in the stable orientation with the lengthwise direction of the egg shape in the Z direction, so when the remote control transmitter 1 is grasped, with the thumb in the direction of the operating buttons 7a and 8a, in order to use the remote control transmitter 1, the X direction, Y direction, and Z direction for detecting accelerations in the three-axis acceleration sensor 10 (the X direction sensor 10x, the Y direction sensor 10y, and Z direction sensor 10z) will essentially match each of the directions illustrated in FIG. 6.

When there is an operation from this state combining an input operation wherein an operating button 7a or 8a of the push switches 7 and 8 is pressed and a motion operation wherein the remote control transmitter 1 is shaken in the vertical direction or the horizontal direction, the corresponding control data, as illustrated in Table 1, is generated by the microprocessor 11.

For example, when the remote control transmitter 1 is shaken in the horizontal direction, and the acceleration that is detected by the X direction sensor 10x or the Y direction sensor 10y exceeds a predetermined threshold value, then the microprocessor 11 generates the control data causing the channel received by the television to switch to the next lower channel because of the motion operation direction data in the X direction or the Y direction indicating that there was a motion operation in the X direction or the Y direction and the OFF pressing operation data indicating that there was no pressing operation on either of the push switches 7 or 8. Moreover, if the remote control transmitter 1 were shaken in the horizontal direction during a pressing operation on the push switch 8, then the microprocessor 11 would generate control data for causing the channel that is received by the television to switch to the next higher channel because of the motion operation direction data in the X direction or the Y direction and the ON pressing operation data for the push switch 8 indicating that there has been a pressing operation for the push switch 8.

Additionally, when the remote control transmitter 1 is shaken in the vertical direction without a pressing operation on either of the push switches 7 or 8, and the acceleration detected by the Z direction sensor 10z exceeds the threshold value, then the microprocessor 11 generates control data to reduce the volume of the television because of the Z direction motion operation direction data indicating that there has been a motion operation in the Z direction, and the OFF pressing operation data indicating that there has been no pressing operation of the push switches 7 and 8.

The control data that is generated by the microprocessor 11 is sent to the RF communications module 12 and transmitted from the transceiver antenna 13 to the device to be controlled (the television) by a radio signal, for example, in the Bluetooth format. As a result, the television that receives this control data performs an action in accordance with the control data. Moreover, the control data is also outputted to the audio IC 14 from the microprocessor 11, to produce a statement from the speaker 5 as indicated by the Table 1 in accordance with the content of the control data.

Instead of the acceleration sensor 10 for detecting accelerations in the axial directions, or in conjunction with the acceleration sensor 10, a gyroscope for detecting angular velocity around axes may also be used to detect the motion operations of the remote control transmitter 1 itself as rotational motion operations around axes.

When the remote control transmitter 1 is grasped in order to use the remote control transmitter 1 that is in the stable orientation, then, as described above, each of the X direction, Y direction, and Z direction from the remote control transmitter 1, with the direction of the arm of the operator being the X direction, will essentially match the directions illustrated in FIG. 6, assumed from the direction of the operating buttons 7a and 8a and the vertical axial line connecting the center of mass G and the stable portion B. Consequently, if a gyroscope is attached within the case 2 for detecting the angular velocity around any of the axes passing through the center of the remote control transmitter 1, with the respective axes of the X direction, Y direction, and Z direction in FIG. 6 being the X axis, the Y axis, and the Z axis, then the motion operations for rotational motion operations of the remote control transmitter 1 around these axes (that is, in the pitch, roll, and yaw directions) will be detected.

For example, if a gyroscope is attached for detecting the angular velocity around the Z axis, then the motion operation around the Z axis (the yaw motion) will be detected by a rotational operation of the remote control transmitter 1 around the Z axis in the vertical direction, making it possible to perform control remotely by sending, to the device to be controlled, control data in accordance with the rotational motion operation direction data around the Z axis.

Furthermore, if a gyroscope is attached for detecting the angular velocity around the X axis, then a motion operation around the X axis (in the pitch direction) will be detected when the arm that holds the remote control transmitter 1 is twisted, making it possible to control remotely the device to be controlled through control data in accordance with the rotational motion operation direction data around the X axis.

Thus, those skilled in the art will readily recognize numerous adaptations and modifications, which can be made to the present invention which fall within the scope of the present invention as defined in the claims.

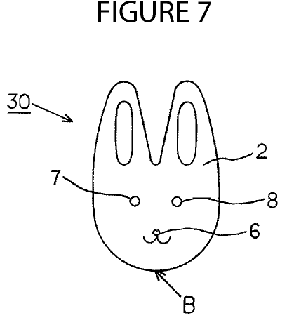

For example, while in the examples set forth above the case 2 was shaped as an egg over all, insofar as the outer peripheral surface of the bottom surface side of the case 2 is a convex surface in the range of the stable portion B that is determined from the position of the center of gravity G, the wobbling action will be performed, and virtually any given shape may be used for the remaining outer peripheral surfaces, where any given external shape design that is appropriate for a mascot, such as in the remote control transmitter 30 illustrated in FIG. 7, may be used. In FIG. 7, those structures that are identical to, or corresponding to, those in the remote control transmitter 1 are labeled with identical codes.

The outer peripheral surface of the bottom surface side of the case 2 may be formed with a curved surface shape such as the side surface of a cylinder, in which case the case would have a stable orientation on a linear stable portion B.

The push switches 7 and 8 are input operating means provided in order to supplement the generation of other types of control data, and need not necessarily be provided if it is possible to assign all of the control data to only motion operations of the remote control transmitter that can be detected by motion sensors such as acceleration sensors and gyroscopes. In a remote control transmitter that is not provided with the push switches 7 and 8, there is no protrusion of operating buttons from the case, enabling the outer shape of the case to have a more simple design.

The present invention is well suited for remote control transmitters for controlling objects to be controlled remotely through motion operations in predetermined directions of the remote control transmitter itself. It is intended that the scope of the present invention include all foreseeable equivalents to the elements and structures as described with reference to FIGS. 1-7. Accordingly, the invention is to be limited only by the scope of the claims and their equivalents.

1. A remote control transmitter comprising:
a motion sensor for detecting acceleration along a predetermined axis or the angular velocity around a predetermined axis and for outputting a detection signal;
a control circuit element for detecting, from the detection signal that is outputted from the motion sensor, a motion operation on a case thereof, and for generating a specific control data in accordance with the detected motion operation;
an RF module for transmitting the control data to the device to be controlled using a radio signal;
one or more batteries for supplying the driving power supply to the motion sensor, the control circuit element, and the RF module; and
a case for enclosing the motion circuit, control circuit, RF module and battery, wherein:
an object to be controlled is controlled remotely through control data through a motion operation on the case, wherein:
at least an outer peripheral surface on a bottom surface side of the case includes a first convex surface, and the one or more batteries are disposed at the bottom surface side within the case, thereby causing a center of gravity G of the remote control transmitter to be positioned between a center of curvature C of the first convex surface of the outer peripheral surface and the first convex surface, the remote control transmitter thereby being configured to assume a predetermined stable orientation when a stable portion of the of the first convex surface is placed on another flat surface,
the center of curvature C of the first convex surface becomes coincident with an axial line extending in the upward direction of gravity from the center of gravity G in the stable orientation,
the axial line defines a vertical direction, and the motion sensor is positioned in the case so as to detect an acceleration in a predetermined axial direction or an angular velocity around a predetermined axis of rotation, using the vertical direction as a reference; and
the control circuit element detects the motion operation of the case from the detection signal that is outputted from the motion sensor.

2. The remote control transmitter as set forth in claim 1, wherein the motion sensor is a Z acceleration sensor positioned in the case so as to detect an acceleration in the vertical axial direction, with the vertical direction as a reference, or a gyroscope positioned in the case so as to detect an angular velocity around the vertical axis, with the vertical direction as a reference.

3. The remote control transmitter as set forth in claim 1, wherein:
a push switch having an operating button configured to protrude from the outer peripheral surface of the case is also contained within the case; and
the motion sensor is positioned in the case so as to detect an acceleration in a specific axial direction in the horizontal direction, or an angular velocity around a specific axis, with the vertical direction and the direction of the operating button around the axis line as references.

4. The remote control transmitter as set forth in claim 3, wherein the motion sensor comprises a gyroscope for detecting an angular velocity around a specific axis in the horizontal direction.

5. The remote control transmitter as set forth in claim 1, wherein the motion sensor comprises a pair of X and Y acceleration sensors positioned in the case so as to detect, respectively, acceleration in the X and Y directions, which are mutually orthogonal horizontal directions, with the vertical direction as a reference.

6. The remote control transmitter as set forth in claim 5, wherein
the control circuit element detects, from the detection signal that is outputted from the pair of X and Y acceleration sensors, a wobbling operation wherein the case rocks within a contact area between the other flat surface and an are of the outer peripheral surface that is centered on the stable portion; and
emitting means are provided for providing at least one of an audible indication or a visual indication when two or more wobbling operations have been detected within a predetermined time period.

7. The remote control transmitter as set forth in claim 2, wherein the control circuit element detects a click operation on the case from the repetitive outputting, within a specific time period, of a detection signal with a frequency of at least 100 Hz from the motion sensor or from any of the acceleration sensors, and generates a specific control data in accordance with the click operation.

8. The remote control transmitter as set forth in claim 1, further comprising a speaker for outputting a sound in accordance with a motion operation or a click operation that is detected by the control circuit element is contained within the case.

9. The remote control transmitter as set forth in claim 1, wherein:
the outer peripheral surface of the case is shaped as an egg shape wherein one side in the lengthwise direction is a bottom surface side;
the stable portion is located on the bottom surface side; and
in the stable orientation, the lengthwise direction of the egg shape is in the vertical direction.

10. The remote control transmitter as set forth in claim 5, wherein the control circuit element detects a click operation on the case from the repetitive outputting, within a specific time period, of a detection signal with a frequency of at least 100 Hz from the motion sensor or from any of the acceleration sensors, and generates a specific control data in accordance with the click operation.

11. The remote control transmitter as set forth in claim 6, wherein the control circuit element detects a click operation on the case from the repetitive outputting, within a specific time period, of a detection signal with a frequency of at least 100 Hz from the motion sensor or from any of the acceleration sensors, and generates a specific control data in accordance with the click operation.

12. The remote control transmitter as set forth in claim 2, further comprising a speaker for outputting a sound in accordance with a motion operation or a click operation that is detected by the control circuit element is contained within the case.

13. The remote control transmitter as set forth in claim 3, further comprising a speaker for outputting a sound in accordance with a motion operation or a click operation that is detected by the control circuit element is contained within the case.

14. The remote control transmitter as set forth in claim 4, further comprising a speaker for outputting a sound in accordance with a motion operation or a click operation that is detected by the control circuit element is contained within the case.

15. The remote control transmitter as set forth in claim 5, further comprising a speaker for outputting a sound in accordance with a motion operation or a click operation that is detected by the control circuit element is contained within the case.

16. The remote control transmitter as set forth in claim 2, wherein:
the outer peripheral surface of the case is shaped as an egg shape wherein one side in the lengthwise direction is a bottom surface side;
the stable portion is located on the bottom surface side; and
in the stable orientation, the lengthwise direction of the egg shape is in the vertical direction.

17. The remote control transmitter as set forth in claim 3, wherein:
the outer peripheral surface of the case is shaped as an egg shape wherein one side in the lengthwise direction is a bottom surface side;
the stable portion is located on the bottom surface side; and
in the stable orientation, the lengthwise direction of the egg shape is in the vertical direction.

18. The remote control transmitter as set forth in claim 4, wherein:
the outer peripheral surface of the case is shaped as an egg shape wherein one side in the lengthwise direction is a bottom surface side;
the stable portion is located on the bottom surface side; and
in the stable orientation, the lengthwise direction of the egg shape is in the vertical direction.

19. The remote control transmitter as set forth in claim 5, wherein:
the outer peripheral surface of the case is shaped as an egg shape wherein one side in the lengthwise direction is a bottom surface side;
the stable portion is located on the bottom surface side; and
in the stable orientation, the lengthwise direction of the egg shape is in the vertical direction.

20. A remote control transmitter comprising:
a motion sensor for detecting acceleration along a predetermined axis or the angular velocity around a predetermined axis and for outputting a detection signal;
a control circuit element for detecting, from the detection signal that is outputted from the motion sensor, a motion operation on a case thereof, and for generating a specific control data in accordance with the detected motion operation;
an RF module for transmitting the control data to the device to be controlled using a radio signal; and
a case for enclosing the motion circuit, control circuit, RF module and battery, wherein:
an object to be controlled is controlled remotely through control data through a motion operation on the case, wherein:
at least an outer peripheral surface on a bottom surface side of the case includes a first convex surface,
the remote control transmitter is configured to have a center of gravity G that is positioned between a center of curvature C of the first convex surface of the outer peripheral surface and the first convex surface, the remote control transmitter thereby being configured to assume a predetermined stable orientation when a stable portion of the of the first convex surface is placed on another flat surface,
the center of curvature C of the first convex surface becomes coincident with an axial line extending in the upward direction of gravity from the center of gravity G in the stable orientation,
the axial line defines a vertical direction, and the motion sensor is positioned in the case so as to detect an acceleration in a predetermined axial direction or an angular velocity around a predetermined axis of rotation, using the vertical direction as a reference; and
the control circuit element detects the motion operation of the case from the detection signal that is outputted from the motion sensor.
